(19) United States
(12) Patent Application Publication
(10) Pub. No.: US 2009/0231011 A1
(43) Pub. Date: Sep. 17, 2009

(54) CIRCUIT ASSEMBLY FOR DISTRIBUTING AN INPUT SIGNAL

(76) Inventor: Dirk Baldringer, Leverkusen (DE)

Correspondence Address: STETINA BRUNDA GARRED & BRUCKER, 75 ENTERPRISE, SUITE 250, ALISO VIEJO, CA, 92656, US

(21) Appl. No.: 12/302,449

(22) PCT Filed: May 31, 2007
(86) PCT No.: PCT/EP2007/055369

§ 371 Date: Nov. 25, 2008

(30) Foreign Application Priority Data
May 31, 2006 (DE) 10 2006 025 784.7

(51) Int. Cl. H03K 5/08

(52) U.S. Cl. 327/318

(57) ABSTRACT

The invention relates to a circuit arrangement for distorting an audio signal, which is used when a “distorted” signal is to be formed from the clear signal for example of an electric guitar. The circuit simulates the distortion of a vacuum tube circuit. The circuit includes changing the waveform and compressing the signal, which otherwise take place by means of tube circuits.

The intensity of the distortion is determined by the amplification of the circuit itself, and a simple amplifier stage arranged upstream of the control voltage. An increase in the supplied signal by the upstream amplifier results in a higher distortion. By means of an optional adjustable amplifier which can be inserted between the output of the circuit and the input of the circuit part responsible for clipping, the intensity of the clipping can furthermore be adjusted without having to increase the input signal. A sound regulation and volume adjustment may be arranged downstream if necessary.

### CROSS-REFERENCE TO RELATED APPLICATIONS

The present application claims priority to International Application No. PCT/EP2007/055369 which was filed on May 31, 2007 which claims priority to German Patent Application No. 1020006025784.7 filed May 31, 2006.

### STATEMENT RE: FEDERALLY SPONSORED RESEARCH/DEVELOPMENT

Not applicable.

### 1. TECHNICAL FIELD OF THE INVENTION

The invention relates to a circuit arrangement for distorting an input signal, in particular an audio signal, according to claim 1.

Generic circuit arrangements are preferably contained in pre-amplifiers for use by musical instruments, for example by electric guitars. In particular, they are used in pre-amplifiers which are based on simulating a vacuum tube amplifier, including the distortion produced by these pre-amplifiers.

Musical instrument amplifiers, traditionally devices comprising a vacuum tube circuit, have long been used for various instruments. Electric guitars for example generate essentially a clean, non-distorted sine wave. The first guitar amplifiers were so-called combo-amplifiers, which were characterised by the fact that the amplifier unit and the loudspeaker were installed together in one housing. Via this built-in loudspeaker, the sound was rendered in a true and unchanged manner.

Since vacuum tubes were easy to handle and were functional in the circuits which were at that time simple, they were used in amplifier construction. The low complexity of the components, the good availability of inexpensive vacuum tubes, transformers and the like led to the amplifiers becoming widespread. Since the output power of the amplifiers was relatively low, overloading within the individual stages of the amplifier also took place at a very early stage. The signal was additionally distorted for example due to the saturation of the output transmitter.

This distorted signal of the tube amplifiers was nevertheless valued and was even consciously desired as proof of authenticity in the rock ‘n’ roll music of the early 1960s.

The sound of a distorted guitar, caused by the transformation of the non-distorted sine wave into a clipped, almost square wave, was therefore very popular. The overloading of the amplifier, the sound adjustment, the attenuation factor and the rendition properties of the loudspeaker determined the sound of the output signal. This distorted sound differed considerably from the non-distorted sound of a guitar in the rock ‘n’ roll music of the early 1950s.

Since circuits comprising transistors soon replaced the tube circuits, attempts were made to copy this desired distorted sound of the tube amplifiers using transistor circuits

### 2. DESCRIPTION OF RELATED ART

In this connection, a so-called “fuzz box” is known from U.S. Pat. No. 4,180,707 C1 for producing four types of clipping. However, only two types of clipping are supported, defined as “soft” and “hard” clipping. This circuit moreover also does not change the frequency response and cannot by its very nature really simulate the circuit of a vacuum tube.

A transistor circuit with an adjustable degree of distortion, which is intended to replace a tube circuit, is also known from U.S. Pat. No. 3,973,461 C1. However, the result in sound terms does not replace a tube circuit. Finally, U.S. Pat. No. 3,825,409 discloses a transistor circuit for use with an electric guitar, which in sound terms is just as unconvincing as the results of the circuits in the aforementioned publications.

### BRIEF SUMMARY OF THE INVENTION

The object of the invention is therefore to provide a circuit arrangement which generates the most authentic possible distortion of a non-distorted input signal to the same effect as the (earlier) distortion by vacuum tubes.

This object is achieved according to the invention by a circuit arrangement according to claim 1.

In particular, the object of the invention is moreover to eliminate the shortcomings in sound terms of the circuits previously published and to specify a circuit for clipping the signal in order to be able to provide a “musical” instrument amplifier which distorts an input signal in the desired manner.

The circuit arrangement according to the invention and an amplifier installed with this circuit arrangement make it possible in particular for the network to determine how the transistors of the transistor pair are to behave. The advantages here lie in the fact that it is possible to clip the output signal in a manner that can be shaped dynamically.

The clipping of the signal is carried out for example in such a way that the signal in the necessary manner clips the positive half-waves to a more significant extent than the negative half-waves, as a result of which a non-symmetrical clipping takes place. By means of an RC element, the start of clipping can take place earlier for high frequencies than for low frequencies, as a result of which the necessary shaping of the half-waves can take place.

By virtue of the invention, it is now possible to carry out a distortion via a circuit which contains a functional amplifier supplemented by a complementary transistor pair in the counter-coupling. This transistor pair consists for example of an NPN transistor for the positive half-waves and of a PNP transistor for the negative half-waves, which is actuated by a frequency-dependent RC network.

A voltage divider is additionally arranged upstream of the PNP transistor responsible for the negative half-waves, so that the start of clipping for the negative half-waves takes place at a higher, adjustable output voltage. Between the output of the amplifier, for example an operational amplifier, and the input of the RC network, an amplifier may additionally be provided in order to make it possible to set the start of clipping independently of the output signal of the input amplifier.

Further features and advantages of the invention will emerge from the dependent claims and from the following description of preferred examples of embodiments with reference to the drawings.

### BRIEF DESCRIPTION OF THE DRAWINGS

FIG. 1 shows a clipping circuit according to the invention;

FIG. 2 shows an example of a complete circuit arrangement with an operational amplifier;

FIG. 3 shows the complete circuit arrangement with the operational amplifier, including an optional operational amplifier for adjusting the distortion;

FIG. 4 shows the complete circuit arrangement for clipping in a passive resistor network and an optional operational amplifier for adjusting the distortion;

FIG. 5 shows the unprocessed sine signal;

FIG. 6 shows the sine signal clipped non-symmetrically by a diode;

FIG. 7 shows the sine signal clipped symmetrically by anti-parallel diodes;

FIG. 8 shows the signal shaped and clipped non-symmetrically by the first stage;

FIG. 9 how the desired signal shaped and clipped symmetrically by the further, subsequent stages.

### DETAILED DESCRIPTION OF THE INVENTION

The essential aspects and advantages of the invention will be explained below on the basis of a detailed description of one example of embodiment which is given in conjunction with the following drawings.

According to the invention, a circuit arrangement for distorting an audio signal is used when a “distorted” signal is to be formed from the clear signal for example of an electric guitar. The circuit simulates the distortion of a vacuum tube circuit. The circuit includes changing the waveform and compressing the signal, which otherwise take place by means of tube circuits.

The intensity of the distortion is determined by the amplification of the circuit itself, and a simple amplifier stage arranged upstream of the control voltage. An increase in the supplied signal by the upstream amplifier results in a higher distortion. By means of an optional adjustable amplifier which can be inserted between the output of the circuit and the input of the circuit part responsible for clipping, the intensity of the clipping can furthermore be adjusted without having to increase the input signal. A sound regulation and volume adjustment may be arranged downstream if necessary.

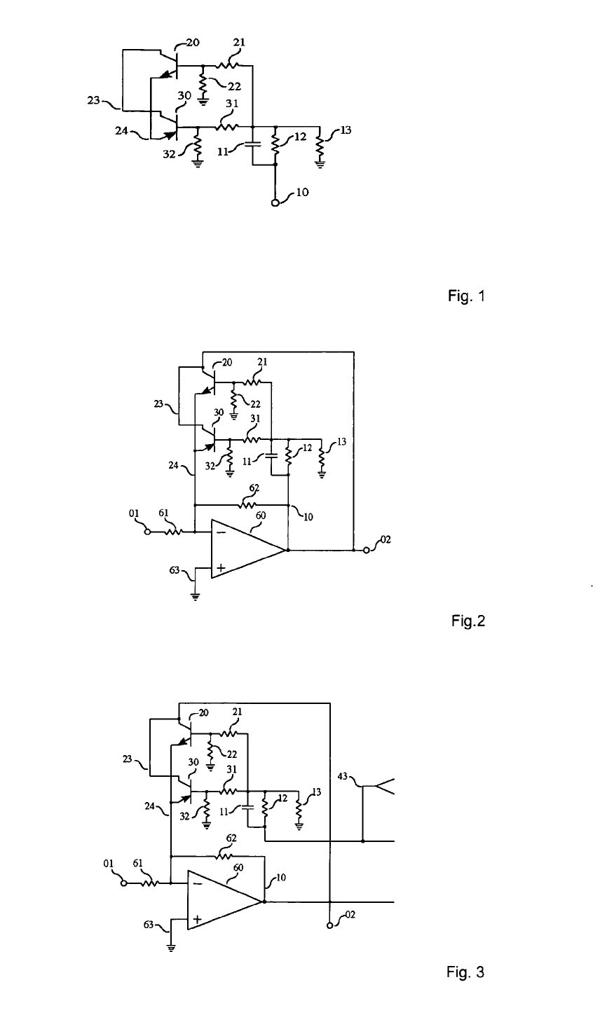

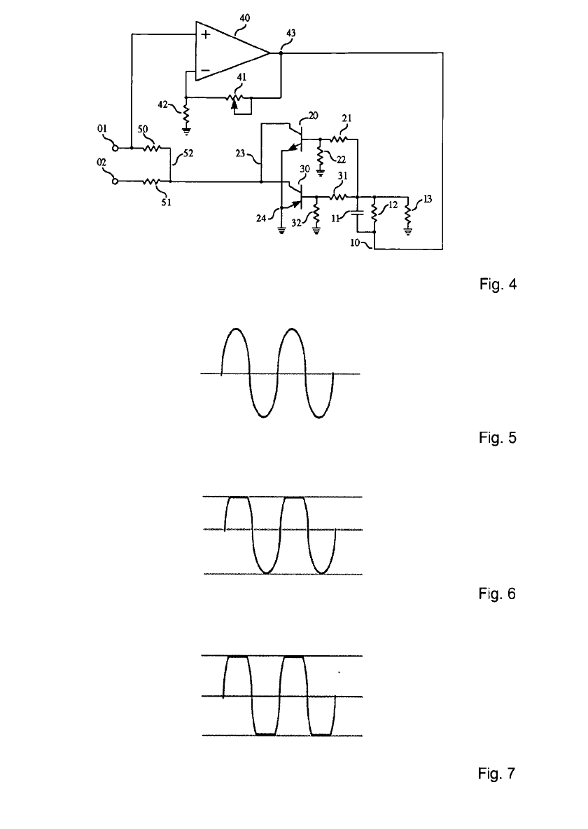

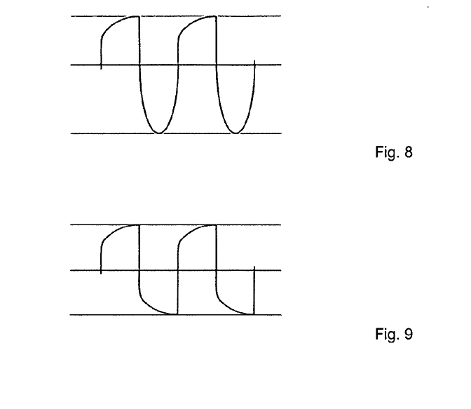

FIG. 1 shows the part of the circuit arrangement according to the invention which is presently regarded as essential. FIGS. 2 to 4 show various circuits which can be expanded by the clipping circuit in FIG. 1. FIGS. 5 to 9 show the various stages of a sine wave from the unprocessed sine wave to the completely shaped, required waveform.

Since an electron tube in a conventional anode circuit results in a phase shift, the simulating circuit arrangement should likewise shift the phase of the signal by 180°. The operational amplifier 60 is therefore designed here as an inverting amplifier and shifts the signal by 180°.

The input resistor 61 and the counter-coupling resistor 62 determine the amplification. The counter-coupling resistor 62 should have a value of between 10 kΩ and 33 kΩ. This value ought not to be too high since the circuit, on account of its basic principle, results not only in a clipping but also in a compression of the signal.

The transistors 20 and 30 are located in the counter-coupling of the operational amplifier 60 and thus change the counter-coupling in a manner dependent on the setting of the parameters. The transistor 20 is responsible for clipping the negative half-wave and the transistor 30 is responsible for clipping the positive half-wave, with reference to the input signal. The signal is fed from the output of the operational amplifier 10 to the bases of the transistors via a filter, here for example a high-pass filter 11, 12 and 13, as a result of which these become conductive.

It is also possible here, as described in FIG. 3, to insert an adjustable amplifier in order to make the start of clipping dependent on the output signal. Furthermore, the amplifier, which is formed here by an operational amplifier, may of course also be formed by a separately constructed transistor circuit; the invention is therefore not limited to the illustrated version. Furthermore, field-effect transistors may also be used for the transistors in the counter-coupling.

The clipping is brought about by the switching-through of the transistors. Since an electron tube has a non-symmetrical clipping, that is to say clips the positive signal to a greater extent than the negative signal, the start of clipping for the transistor 30 can be set by the voltage divider formed by the resistor 31 and the resistor 32. The same applies to the transistor 20, which is responsible for the negative half-wave.

By means of the resistors 31 and 32, the start of clipping is set in such a way that the required, non-symmetrical clipping takes place. This voltage divider may also be formed by adjustable resistors. Since an electron tube not only clips the waveform but rather also changes the actual waveform during the clipping process, this effect can be achieved by the capacitor 11 and the resistors 12 and 13, which here form for example a high-pass filter.

The components consisting of the capacitor 11, the resistor 12 and the resistor 13 form a high-pass, as a result of which the clipping starts earlier at high frequencies than at lower frequencies. Here, the cutoff frequency is set by means of the components consisting of the capacitor 11 and the resistor 13. A variable resistor may also be used for the resistor 13.

Depending on the dimensioning of the resistors 21, 22, 31 and 32, the resistor 13 may also be omitted since the resistors 21, 22, 31 and 32 can additionally perform this function. The resistor 12 forms a bypass for low frequencies, as a result of which it is not only high frequencies that are clipped but rather also the low frequencies. This arrangement leads to the situation in which only the rising edges are clipped earlier than the falling edges, thereby bringing about the necessary shaping of the waveform.

Since a plurality of tube stages are arranged one behind the other in an amplifier circuit constructed with electron tubes, a plurality of these should also be arranged one behind the other in this circuit published here, in order to achieve the same result.

Typical values, which are nonetheless given only by way of example, for the components used in the circuit of FIG. 1 are shown in the following table:

Resistor 12: 10k
Resistor 13: 39k
Resistor 21: 4.7k
Resistor 22: 47k
Resistor 31: 22k
Resistor 32: 15k
Resistor 61: 4.7k
Resistor 62: 22k
Capacitor 11: 47 nF
Transistor 20: BC557B or the like
Transistor 20: BC547B or the like

1. Circuit arrangement for clipping a signal comprising an input control signal (10) and a transistor pair which comprises a first transistor (20) and a second transistor (30), wherein the behavior of the first transistor (20) and of the second transistor (30) can be controlled via a control signal, characterized in that the transistor pair comprises complementary transistors and a filter is arranged between the input signal (10) and the control signal, wherein a first voltage divider (21, 22) is provided for the first transistor (20) and a second voltage divider (31, 32) is provided for the second transistor (30).

2. The circuit arrangement according to claim 1, further comprising an amplifier, which is designed as an inverting amplifier (60), which generates an output signal and has an input via which an input signal that is to be transformed into the output signal can be applied to the amplifier, wherein the amplifier (60) comprises a counter-coupling which is formed by the circuit arrangement and via which the output signal is placed onto the input signal of the amplifier (60), and the circuit arrangement forms a second counter-coupling by the two complementary transistors, said second counter-coupling having a control voltage that can be influenced by a filter.

3. The circuit arrangement according to claim 2, characterized in that arranged upstream of the control voltage resulting from the filter and fed to the transistors of the transistor pair is a resistor, an adjustable resistor and/or a voltage divider, via which the start of clipping for the transistors (20, 30) can be set.

4. The circuit arrangement of claim 1 further comprising a circuit for distorting an input signal, characterized in that the amplifier (60) is an operational amplifier.

5. The circuit arrangement of claim 4 wherein the circuit for distorting an input signal is characterized in that the voltage divider is formed by a grounded resistor and a resistor connector to the filter.

6. The circuit arrangement of claim 5 wherein the circuit for distorting an input signal is characterized in that the filter is formed by a capacitor (11) and a resistor (12) connected in parallel with the capacitor, which are connected to the output of the amplifier (60), and also a grounded resistor (13), wherein the three components are connected to the inputs of the transistors.

7. The circuit arrangement of claim 6 wherein the circuit for distorting an input signal is characterized in that the filter is a high-pass filter.

8. The circuit arrangement of claim 7 wherein the circuit for distorting an input signal is characterized in that the filter is a low-pass filter.

9. The circuit arrangement of claim 4 wherein the circuit for distorting an input signal is characterized in that the filter is a band-pass filter.
